(19) United States
(12) Patent Application Publication
(10) Pub. No.: US 2026/0033230 A1
(43) Pub. Date: Jan. 29, 2026

(54) LIGHT-EMITTING SUBSTRATE, DISPLAY PANEL, AND MANUFACTURING METHOD OF THE SAME

(71) Applicant: HKC CORPORATION LIMITED, SHENZHEN (CN)

(72) Inventors: Dongmei WEI, SHENZHEN (CN); Chuan WU, SHENZHEN (CN); Zhonglin CAO, SHENZHEN (CN); Xiaoxiao YUAN, SHENZHEN (CN); Fengzhen DANG, SHENZHEN (CN); Wenyu YI, SHENZHEN (CN); Yao LI, SHENZHEN (CN); Jie CHEN, SHENZHEN (CN); Lidan YE, SHENZHEN (CN)

(73) Assignee: HKC CORPORATION LIMITED, SHENZHEN (CN)

(21) Appl. No.: 19/263,632

(22) Filed: Jul. 9, 2025

(30) Foreign Application Priority Data
Jul. 23, 2024 (CN) 202410999437.4

(51) Int. Cl. H10K 71/60; H10K 59/12; H10K 59/131

(52) U.S. Cl. CPC H10K 71/60; H10K 59/1201; H10K 59/131

(57) ABSTRACT

A light-emitting substrate, a display panel, and a manufacturing method of the same. The method includes: preparing a light-emitting substrate, preparing a drive substrate, and aligning and connecting the light-emitting substrate with the drive substrate. The preparing a light-emitting substrate includes: preparing a metal pattern layer and a first protective layer on opposite sides of the glass substrate; where the first protective layer covers protruding portions of the conductive portions; and preparing a light-emitting device layer on the metal pattern layer. The preparing a drive substrate includes: preparing a drive circuit layer, drive electrodes, and an insulating layer on a silicon substrate; and preparing a second protective layer on the insulating layer, where the second protective layer covers exposed portions of the drive electrodes.

### CROSS-REFERENCE TO RELATED APPLICATIONS

The present application claims priority of Chinese Patent Application No. 202410999437.4, filed on Jul. 23, 2024, the entire contents of which are hereby incorporated by reference in their entirety.

### TECHNICAL FIELD

The present disclosure relates to the field of display technologies, and in particular to a light-emitting substrate, a display panel, and a manufacturing method of the same.

### BACKGROUND

A single-crystal silicon drive backplate is a drive substrate formed by semiconductor devices fabricated through Complementary Metal Oxide Semiconductor (CMOS) processes as driving units. Compared to conventional Active-matrix organic light-emitting diode (AMOLED) panels that utilize amorphous silicon, microcrystalline silicon, or low-temperature polycrystalline silicon thin-film transistors as backplates, the single-crystal silicon drive backplate demonstrates significantly higher carrier mobility. Consequently, Silicon-based Organic Light-Emitting Diode (SiOLED) display panels are currently the highest-performance display technology applied in AR/VR products.

Currently, the silicon-based OLED display panel integrates the conventional externally-bonded display chip into the silicon-based drive backplate. The fabrication method thereof involves vapor-depositing OLED light-emitting devices onto a silicon-based drive substrate. Specifically, this process includes: depositing to form an anode; forming a pixel definition layer; and sequentially, depositing an organic emissive layer and a cathode. This approach enables the production of subpixels with smaller dimensions, thereby achieving display fineness exceeding retinal resolution, further with advantages such as high resolution, high integration density, low power consumption, compact size, and lightweight structure.

However, directly vapor-depositing OLED emissive devices onto the silicon-based drive substrate may easily affect the silicon-based drive circuits, causing damage to the drive circuits and rendering them unusable, thereby increasing costs.

### SUMMARY OF THE DISCLOSURE

The present disclosure provides a light-emitting substrate, a display panel, and a manufacturing method of the same, aimed at solving the problem in the prior art that directly vapor-depositing OLED light-emitting devices on a silicon-based drive substrate easily causes damage to the drive circuit.

To solve the above technical problem, the present disclosure provides a manufacturing method of a display panel, including:
preparing a light-emitting substrate, including:
   providing a glass substrate;
   preparing a metal pattern layer on a side of the glass substrate, and preparing a first protective layer on an opposite side of the glass substrate; wherein the metal pattern layer includes an electrode layer and conductive portions that are interconnected; the electrode layer is disposed on the side of the glass substrate, and the conductive portions penetrate the glass substrate to the opposite side of the glass substrate; a portion of each of the conductive portions protrudes from the opposite side; the first protective layer covers the portions of the conductive portions; and
   preparing a light-emitting device layer on a side of the metal pattern layer away from the glass substrate;
preparing a drive substrate, including:
   providing a silicon substrate; and preparing a drive circuit layer, drive electrodes, and an insulating layer on the silicon substrate; wherein the drive electrodes are electrically coupled to the drive circuit layer and extend through the insulating layer to be exposed; and
   preparing a second protective layer on a side of the insulating layer away from the silicon substrate; wherein the second protective layer covers exposed portions of the drive electrodes; and
aligning and connecting the light-emitting substrate with the drive substrate, including:
   removing the first protective layer and the second protective layer; and
   aligning and connecting the conductive portions of the light-emitting substrate with the drive electrodes of the drive substrate.

To solve the above technical problem, the present disclosure further provides a light-emitting substrate, including:
a glass substrate;
a metal pattern layer, including an electrode layer and conductive portions that are interconnected; wherein the electrode layer is disposed on a side of the glass substrate, and the conductive portions penetrate the glass substrate to an opposite side of the glass substrate; a portion of each of the conductive portions protrudes from the opposite side;
a protective layer, disposed on the opposite side of the glass substrate and covering the portions of the conductive portions; and
a light-emitting device layer, disposed on a side of the electrode layer away from the glass substrate.

To solve the above technical problem, the present disclosure further provides a display panel, including a drive substrate and a light-emitting substrate that are connected together; wherein the display panel is prepared by the manufacturing method as above.

### BRIEF DESCRIPTION OF THE DRAWINGS

To more clearly illustrate the technical solutions of the embodiments of the present disclosure, the following is a brief introduction to the drawings used in the description of the embodiments. It should be understood that the drawings described below are merely some embodiments of the present disclosure. For those skilled in the art, other drawings can be obtained without any creative effort based on these drawings.

FIG. 1 is a structural schematic view of a display panel according to some embodiments of the present disclosure.

FIG. 2 is a flowchart of a manufacturing method of a display panel according to some embodiments of the present disclosure.

FIG. 3 is a flowchart of operation S10 in the manufacturing method as illustrated in FIG. 2 according to some embodiments of the present disclosure.

FIG. 4 is a schematic diagram of a manufacturing process of a light-emitting substrate according to the embodiments as illustrated in FIG. 3.

FIG. 5 is a flowchart of operation S20 in the manufacturing method as illustrated in FIG. 2 according to some embodiments of the present disclosure.

FIG. 6 is a schematic diagram of a manufacturing process of a drive substrate according to the embodiments as illustrated in FIG. 5.

FIG. 7 is a flowchart of operation S12 in the manufacturing method as illustrated in FIG. 3 according to some embodiments of the present disclosure.

FIG. 8 is a schematic diagram of the manufacturing process of the operation S12 in the manufacturing method as illustrated in FIG. 7.

FIG. 9 is a flowchart of operation S12 in the manufacturing method as illustrated in FIG. 3 according to other embodiments of the present disclosure.

FIG. 10 is a schematic diagram of the manufacturing process of the operation S12 in the manufacturing method as illustrated in FIG. 9.

FIG. 11 is a flowchart of operation S13 in the manufacturing method as illustrated in FIG. 3 according to some embodiments of the present disclosure.

FIG. 12 is a schematic diagram of the manufacturing process of the operation S13 in the manufacturing method as illustrated in FIG. 11.

FIG. 13 is a flowchart of operation S20 in the manufacturing method as illustrated in FIG. 2 according to other embodiments of the present disclosure.

FIG. 14 is a schematic diagram of a manufacturing process of a drive substrate according to the embodiments as illustrated in FIG. 13.

FIG. 15 is a flowchart of operation S20 in the manufacturing method as illustrated in FIG. 2 according to further other embodiments of the present disclosure.

FIG. 16 is a schematic diagram of a manufacturing process of a drive substrate according to the embodiments as illustrated in FIG. 15.

FIG. 17 is a flowchart of operation S30 in the manufacturing method as illustrated in FIG. 2 according to some embodiments of the present disclosure.

FIG. 18 is a schematic diagram of a process for connecting two substrates according to the embodiments as illustrated in FIG. 17.

FIG. 19 is a plane structural schematic view of a metal pattern layer according to some embodiments of the present disclosure.

FIG. 20 is a plane structural schematic view of a drive electrode according to some embodiments of the present disclosure.

FIG. 21 is a plane structural schematic view of a metal pattern layer according to other embodiments of the present disclosure.

FIG. 22 is a plane structural schematic view of a drive electrode according to other embodiments of the present disclosure.

### DETAILED DESCRIPTION

The following description, in conjunction with the accompanying drawings, provides a detailed explanation of the technical solutions of the embodiments of the present disclosure.

In the following description, specific details such as specific system structures, interfaces, and technologies are provided for the purpose of explanation rather than limitation, in order to facilitate a thorough understanding of the present disclosure.

The technical solutions in the embodiments of the present disclosure will be described in detail with reference to the accompanying drawings. It should be noted that the embodiments described herein are only some of the embodiments of the present disclosure and are not intended to be exhaustive. All other embodiments obtained by those skilled in the art without making creative contributions based on the embodiments of the present disclosure are within the scope of the present disclosure.

The terms “first,” “second,” and “third” used in the present disclosure are for descriptive purposes only and should not be understood as indicating or implying relative importance or the number of technical features indicated. Therefore, features defined with “first,” “second,” or “third” may explicitly or implicitly include at least one of the features indicated. In the description of the present disclosure, “multiple” means at least two, such as two, three, etc., unless otherwise explicitly specified. All directional indications (such as up, down, left, right, front, back, etc.) in the embodiments of the present disclosure are intended solely to explain relative positions and movements of components in a specific orientation (as shown in the drawings). When the specific orientation changes, the directional indications also change accordingly. Furthermore, the terms “include” and “have,” as well as any variations thereof, are intended to cover non-exclusive inclusion. For example, a process, method, system, product, or device that includes a series of steps or units is not limited to the steps or units listed, but may optionally include steps or units not listed, or may optionally include other steps or units inherent to such process, method, product, or device.

The term “embodiment” as used herein means that the specific features, structures, or characteristics described in connection with an embodiment may be included in at least one embodiment of the present disclosure. The appearance of this term at various locations in the specification does not necessarily refer to the same embodiment, nor does it indicate that the embodiments are mutually exclusive or independent alternatives. Those skilled in the art will understand that the embodiments described herein may be combined with other embodiments.

The present disclosure will be described in detail with reference to the accompanying drawings and embodiments.

Referring to FIG. 1, FIG. 1 is a structural schematic view of a display panel according to some embodiments of the present disclosure. In the embodiments, a display panel 100 is provided, which includes a drive substrate 20 and a light-emitting substrate 10 that are connected together.

The drive substrate 20 includes a silicon substrate 21, a drive circuit layer 22, a connecting electrode layer 24, and an insulating layer 23, which are stacked in sequence. Specifically, in some embodiments, the silicon substrate 21 may be configured to be a single-crystal silicon base substrate.

The drive circuit layer 22 includes multiple pixel drive circuit units, each of which includes a drive device; in some embodiments, a CMOS device may be applied to be the drive device, so as to form the pixel drive circuit unit, thereby driving a light-emitting unit L to emit light.

The connecting electrode layer 24 is electrically coupled to the drive circuit layer 22. The connecting electrode layer 24 includes multiple drive electrodes 241, which are electrically connected to the pixel drive circuit units, enabling drive signals to be transmitted from the pixel drive circuit units to the drive electrodes 241 and then further transmitted through the drive electrodes 241 to the light-emitting substrate 10.

The insulating layer 23 is disposed on a side of the drive circuit layer 22 away from the silicon substrate 21 and defines multiple via holes 231. The drive electrodes 241 pass through the insulating layer 23 and are electrically connected to the pixel drive circuit units. A portion of each drive electrode 241 is exposed for alignment and connecting with the light-emitting substrate 10. The insulating layer 23 may include an organic insulating layer 23 and/or an inorganic insulating layer 23. The insulating layer 23 may specifically be configured to be the inorganic insulating layer 23, which is made of an inorganic insulating material such as silicon dioxide, silicon nitride, or silicon oxide.

The light-emitting substrate 10 includes conductive portions 122, a glass substrate 11, an electrode layer 121, and a light-emitting device layer LD, which are stacked in sequence. Specifically, the conductive portions 122 and the electrode layer 121 are disposed on opposite sides of the glass substrate 11; the electrode layer 121 includes multiple anode electrodes 1211 and an auxiliary cathode (auxiliary electrode 1212) arranged around the multiple anode electrodes 1211. The glass substrate 11 defines multiple glass through holes 111, and the conductive portions 122 are each electrically connected to a corresponding anode electrode 1211 or the auxiliary cathode through a corresponding glass through hole 111.

The light-emitting device layer LD is disposed on a side of the electrode layer 121 away from the glass substrate 11 and includes a pixel definition layer 13, light-emitting layers 14, and a cathode electrode 15. The pixel definition layer 13 is disposed on a side of the electrode layer 121 away from the glass substrate 11 and is patterned to define multiple pixel openings 131, which are disposed in correspondence with the anodes, exposing the anode electrodes 1211; the light-emitting layers 14 are each disposed within a corresponding pixel opening 131 and in contact with a corresponding anode electrode 1211; the cathode electrode 15 is disposed on a side of the light-emitting layers 14 away from the glass substrate 11 and in contact with the light-emitting layers 14; the cathode electrode 15 may specifically be a full-surface electrode and extend to an outside of the pixel definition layer 13 to make electrical contact with the auxiliary cathode. Each light-emitting layer 14 forms a light-emitting unit L with the anode electrode 1211 and the cathode electrode 15 it contacts. In some embodiments, the light-emitting layers 14 may be of different colors, such as a red light-emitting layer 14, a green light-emitting layer 14, and a blue light-emitting layer 14, thereby forming a red light-emitting unit L, a green light-emitting unit L, and a blue light-emitting unit L, to achieve color display. In some embodiments, the light-emitting layer 14 may be a white light-emitting layer 14, thereby forming a white light-emitting unit L. A color filter layer may be arranged on a side of the cathode away from the glass substrate 11, and color display may be achieved through the color filter layer. The light-emitting substrate 10 may further include an encapsulation layer 16 for sealing the light-emitting units L, thereby preventing the ingress of external water and oxygen, and thus preventing the light-emitting units L from malfunctioning due to the ingress of external water and oxygen.

By aligning and connecting the conductive portions 122 with the drive electrodes 241, the drive signals from the drive substrate 20 can be transmitted through the conductive portions 122 to the light-emitting units L, thereby driving the light-emitting units L to emit light.

In the embodiments, by forming the light-emitting device layer LD on the glass substrate 11 to prepare the light-emitting substrate 10 of an independent structure, the light-emitting substrate 10 and the drive substrate 20 may be prepared separately, which may not only improve production efficiency but also effectively avoid damaging the pixel drive circuits during the process of preparing the light-emitting device layer LD directly on the drive substrate 20, thereby preventing a decrease in product yield. Additionally, by adopting the glass substrate 11 as a base substrate for the light-emitting substrate 10, the glass substrate 11 offers better stability and is less prone to deformation due to temperature changes, which may maintain the stability and electrical performance of the light-emitting devices. Further, the glass substrate 11 has better light transmittance, which contributes to enhancing the brightness of the display panel 100. Furthermore, by disposing the light-emitting device layer LD on the glass substrate 11, the light-emitting substrate 10 may be manufactured in larger sizes.

Specifically, the display panel 100 may be prepared using the manufacturing method described below, which is detailed in the subsequent description and explanation.

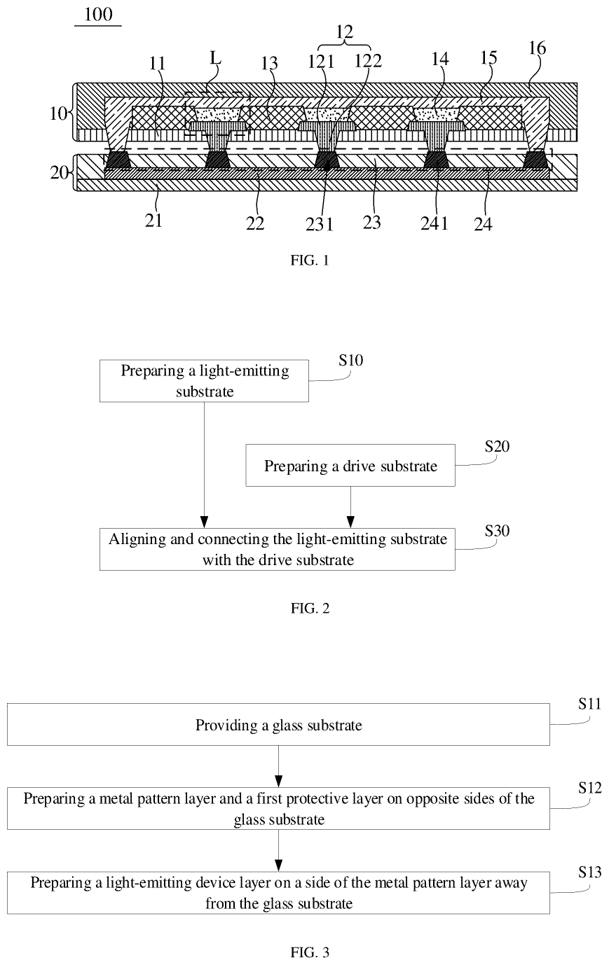

Referring to FIG. 2, FIG. 2 is a flowchart of a manufacturing method of a display panel according to some embodiments of the present disclosure. In the embodiment, a manufacturing method of a display panel 100 is provided, which includes operations at blocks illustrated in FIG. 2.

At block S10: Preparing a light-emitting substrate 10.

At block S20: Preparing a drive substrate 20.

At block S30: Aligning and connecting the light-emitting substrate 10 with the drive substrate 20.

The operations S10 and S20 are not sequential; that is, the light-emitting substrate 10 and the drive substrate 20 are fabricated separately, and S10 and S20 may be performed according to production requirements without a specific sequence.

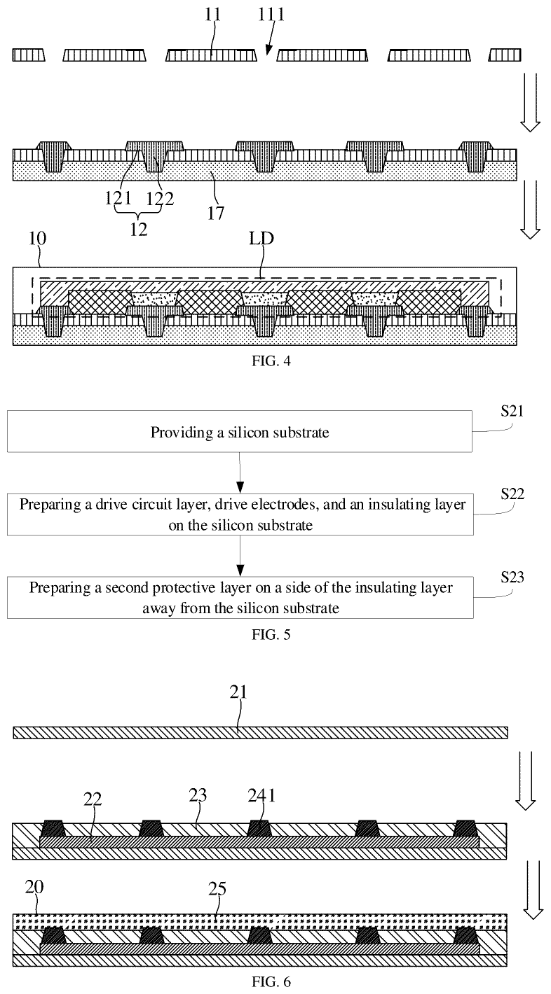

Referring to FIGS. 3 and 4, FIG. 3 is a flowchart of operation S10 in the manufacturing method as illustrated in FIG. 2 according to some embodiments of the present disclosure, and FIG. 4 is a schematic diagram of a manufacturing process of a light-emitting substrate according to the embodiments as illustrated in FIG. 3. The S10 for preparing the light-emitting substrate 10 specifically includes operations at blocks illustrated in FIG. 3.

At block S11: Providing a glass substrate 11.

At block S12: Preparing a metal pattern layer 12 and a first protective layer 17 on opposite sides of the glass substrate 11.

At block S13: Preparing a light-emitting device layer LD on a side of the metal pattern layer 12 away from the glass substrate 11.

In S12, the metal pattern layer 12 includes the electrode layer 121 and conductive portions 122 that are interconnected. The electrode layer 121 is disposed on a side of the glass substrate 11, while the conductive portions 122 penetrate the glass substrate 11 to an opposite side of the glass substrate 11 and partially protrude from the opposite side. The first protective layer 17 covers protruding portions of the conductive portions 122.

Specifically, in S12, multiple glass through holes 111 are defined on the glass substrate 11 to allow metal material to fill the glass through holes 111 and protrude from the opposite side of the glass substrate 11 during the preparation process of the metal pattern layer 12, thereby forming the conductive portions 122. The conductive portions 122 are configured for alignment and connecting with the drive electrodes 241 of the drive substrate 20 to transmit drive signals to the light-emitting substrate 10.

Furthermore, in S12, the first protective layer 17 is formed on the opposite side of the glass substrate 11 to cover the protruding portions of the conductive portion 122, thereby protecting the conductive portions 122 to ensure connecting reliability and prevent the conductive portions 122 from being exposed and damaged during subsequent processes. For example, contact with equipment during subsequent processes could easily damage the conductive portions 122 and result in connecting defects during subsequent alignment and connecting, which might lead to signal transmission abnormalities. In addition, damage to the conductive portions 122 during handling, storage, and other operations may be prevented.

Referring to FIGS. 5 and 6, FIG. 5 is a flowchart of operation S20 in the manufacturing method as illustrated in FIG. 2 according to some embodiments of the present disclosure, and FIG. 6 is a schematic diagram of a manufacturing process of a drive substrate according to the embodiments as illustrated in FIG. 5. In the embodiments, the operation S20 for preparing the drive substrate 20 specifically include operations at blocks illustrated in FIG. 5.

At block S21: Providing a silicon substrate 21.

At block S22: Preparing a drive circuit layer 22, drive electrodes 241, and an insulating layer 23 on the silicon substrate 21.

At block S23: Preparing a second protective layer 25 on a side of the insulating layer 23 away from the silicon substrate 21.

In S22, the drive electrodes 241 are electrically coupled to the drive circuit layer 22 and extend through the insulating layer 23 to be exposed, for alignment and connecting with the conductive portions 122 of the light-emitting substrate 10, which allows the drive signals to be transmitted through the drive electrodes 241 and the conductive portion 122 that are connected together to the light-emitting units L, thereby driving the light-emitting units L to emit light.

In S23, the second protective layer 25 covers the exposed portions of the drive electrodes 241, thereby protecting the drive electrodes 241 to ensure connecting reliability and prevent damage to the drive electrodes 241 from exposure to external forces or other external factors during subsequent handling, storage, or other processes, where the damage could lead to connecting defects during subsequent alignment and connecting, resulting in abnormal signal transmission and other issues.

In the embodiments, by separately preparing the light-emitting substrate 10 and the drive substrate 20, the production efficiency may be improved. Furthermore, by adopting the silicon substrate 21 as a base substrate for the drive substrate 20, the advantages of the silicon-based drive substrate 20 are retained. Additionally, by adopting the glass substrate 11 as a base substrate for the light-emitting substrate 10, costs are reduced, and the glass substrate 11 has better stability and is less prone to deformation due to temperature changes, which is beneficial for maintaining the stability and electrical performance of the light-emitting devices. In addition, the glass substrate 11 has better light transmittance, which is advantageous for improving the brightness of the display panel 100. Furthermore, by forming the light-emitting device layer LD on the glass substrate 11, it is possible to achieve a large-sized light-emitting substrate 10.

In some embodiments, the operation S10 further includes: defining multiple glass through holes 111 on the glass substrate 11. Specifically, laser-induced etching may be applied to define the glass through holes 111; where a laser is first directed at desired locations on the glass substrate 11 to form a modified zone, followed by etching the modified zone with an etching solution, to define the glass through holes 111. By adopting the glass substrate 11 as the base substrate, compared to the silicon-based base substrate, since the glass substrate 11 has better insulating properties, it is not necessary to form an oxide insulating layer on walls of the glass through holes 111, nor is special thin wafer handling technology required, thereby reducing costs. Additionally, due to the excellent insulating properties of the glass substrate 11, electromagnetic coupling effects are minimized during signal transmission, which may effectively reduce signal insertion loss and crosstalk, thereby ensuring signal integrity.

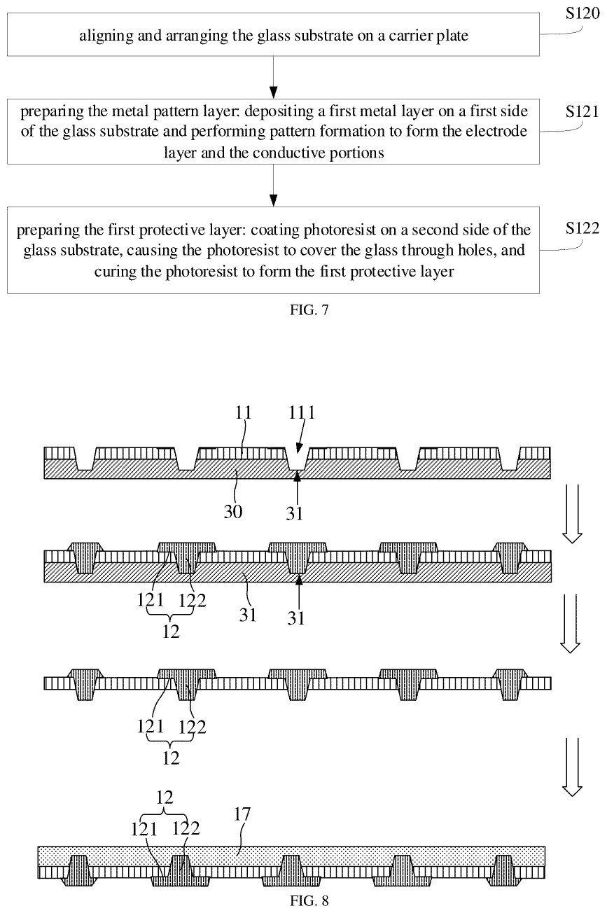

In some embodiments, the operation S12 includes operations at blocks illustrated in FIG. 7, where FIG. 7 is a flowchart of operation S12 in the manufacturing method as illustrated in FIG. 3 according to some embodiments of the present disclosure.

At block S121: preparing the metal pattern layer 12: depositing a first metal layer on a first side of the glass substrate 11 and performing pattern formation to form the electrode layer 121 and the conductive portions 122.

At block S122: preparing the first protective layer 17: coating photoresist PR on a second side of the glass substrate 11, causing the photoresist PR to cover the glass through holes 111, and curing the photoresist PR to form the first protective layer 17.

The first side and the second side of the glass substrate 11 are opposite to each other. It should be noted that the order of S121 and S122 may be interchanged. That is, S121 may precede S122; or S122 may precede S121. It can be understood that the metal pattern layer 12 may be formed first, followed by the first protective layer 17; or the first protective layer 17 may be formed first, followed by the metal pattern layer 12. For details, reference may be made to the following description.

Referring to FIGS. 7 and 8, FIG. 7 is a flowchart of operation S12 in the manufacturing method as illustrated in FIG. 3 according to some embodiments of the present disclosure, and FIG. 8 is a schematic diagram of the manufacturing process of the operation S12 in the manufacturing method as illustrated in FIG. 7. In the illustrated embodiments, S121 precedes S122.

Specifically, S120 is included before S121: aligning and arranging the glass substrate 11 on a carrier plate 30. An upper surface of the carrier plate 30 defines multiple first recesses 31. After the glass substrate 11 is aligned and arranged on the carrier plate 30, the first recesses 31 align with and communicate with the glass through holes 111, i.e., they overlap and communicate in a direction perpendicular to the glass substrate 11. The number of the first recesses 31 on the carrier plate 30 is greater than or equal to the number of glass through holes 111. The shape and depth of the first recesses 31 may be designed according to the protruding portions of the conductive portions 122. It should be noted that after the glass substrate 11 is aligned and arranged on the carrier plate 30, it is necessary to ensure that the second side of the glass substrate 11 is tightly attached to the carrier plate 30 to prevent a short circuit in the conductive portion 122 caused by the first metal layer overflowing.

In S121, the first metal layer is deposited on the first side of the glass substrate 11 and into the glass through holes 111 and the first recesses 31 to fill the glass through holes 111 and the first recesses 31, thereby forming the conductive portions 122. The first metal layer is then patterned to form the electrode layer 121. The electrode layer 121 specifically includes the auxiliary electrode 1212 that is disposed outermost and the anode electrodes 1211 that are disposed in a display region; the conductive portions 122 includes anode connecting portions 1221 and a cathode connecting portion 1222, with the conductive portions 122 connected to the anode electrodes 1211 being the anode connecting portions 1221, and the conductive portion 122 connected to the auxiliary electrode 1212 being the cathode connecting portion 1222. The anode electrode 1211 is configured for electrical connection with the light-emitting layer 14, and the auxiliary electrode 1212 is configured for electrical connection with the cathode electrode 15.

It can be understood that before performing the operation S122, it is necessary to separate the carrier substrate 30 from the glass substrate 11, flip the glass substrate 11 such that the second side of the glass substrate 11 is on top and the first side is on bottom, and then form the first protective layer 17 on the second side. In S122, since the photoresist PR is a commonly used material for preparing the display panel 100, using photoresist PR to form the first protective layer 17 is more convenient, such that there is no need to prepare materials specifically for forming the protective layer. Additionally, using the photoresist PR to form the first protective layer 17 ensures that, after curing, the photoresist PR forms a more reliable bond with the glass substrate 11, reducing the risk of delamination or peeling, and providing better protection for the protruding portions of the conductive portions 122.

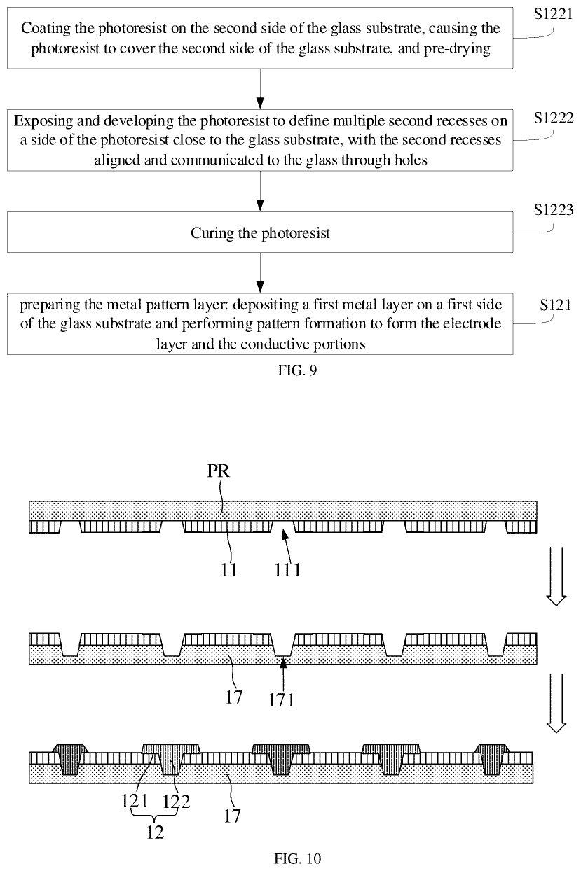

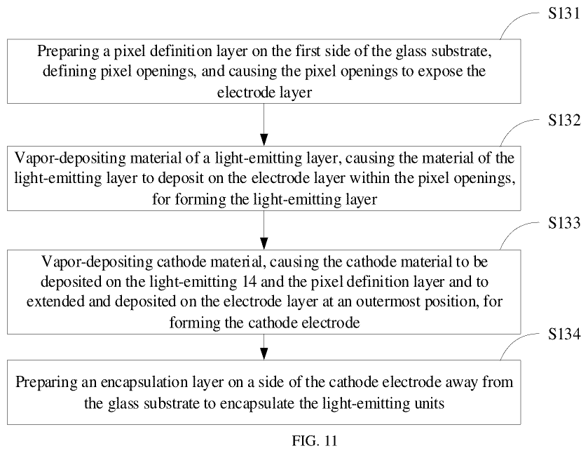

Referring to FIGS. 9 and 10, FIG. 9 is a flowchart of operation S12 in the manufacturing method as illustrated in FIG. 3 according to other embodiments of the present disclosure, and FIG. 10 is a schematic diagram of the manufacturing process of the operation S12 in the manufacturing method as illustrated in FIG. 9. In the illustrated embodiments, S122 precedes S123.

Specifically, the operation S122 includes operations at blocks illustrated in FIG. 9.

At block S1221: Coating the photoresist PR on the second side of the glass substrate 11, causing the photoresist PR to cover the second side of the glass substrate 11, and pre-drying.

At block S1222: Exposing and developing the photoresist PR to define multiple second recesses 171 on a side of the photoresist PR close to the glass substrate 11, with the second recesses 171 aligned and communicated to the glass through holes 111.

At block S1223: Curing the photoresist PR.

In S1222, the photoresist PR is exposed using a mask, followed by development, such that the side of the photoresist PR close to the glass substrate 11 defines the multiple second recesses 171 corresponding to the glass through holes 111. The shape and depth of the second recesses 171 may be set according to the shape and height of the protruding portions of the conductive portions 122.

The glass substrate 11 is then flipped, and S21 is performed, where the first metal layer is deposited on the first side of the glass substrate 11 and into the glass through holes 111 and the second recesses 171 to fill the glass through holes 111 and the second recesses 171, thereby forming the conductive portions 122. The first metal layer is then patterned, to form the electrode layer 121. Compared to the previous embodiments, in the present embodiments, the carrier plate 30 is not required to form the protruding portions of the conductive portion 122. The first protective layer 17 serves both to form the protruding portions of the conductive portions 122 and to protect the protruding portions of the conductive portions 122.

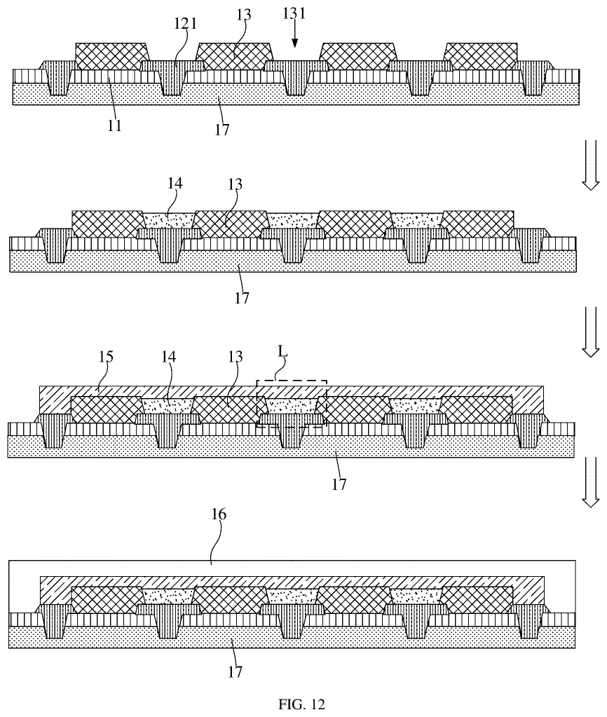

Referring to FIGS. 11 and 12, FIG. 11 is a flowchart of operation S13 in the manufacturing method as illustrated in FIG. 3 according to some embodiments of the present disclosure, and FIG. 12 is a schematic diagram of the manufacturing process of the operation S13 in the manufacturing method as illustrated in FIG. 11. In the embodiments, after S12, S13 is performed, which specifically includes operations at blocks illustrated in FIG. 11.

At block S131: Preparing a pixel definition layer 13 on the first side of the glass substrate 11, defining pixel openings 131, and causing the pixel openings 131 to expose the electrode layer 121.

At block S132: Vapor-depositing material of a light-emitting layer 14, causing the material of the light-emitting layer 14 to deposit on the electrode layer 121 within the pixel openings 131, for forming the light-emitting layer 14.

At block S133: Vapor-depositing cathode material, causing the cathode material to be deposited on the light-emitting layer 14 and the pixel definition layer 13 and to be extended and deposited on the electrode layer 121 at an outermost position, for forming the cathode electrode 15.

In S131, the pixel definition layer 13 may be patterned using photoresist PR, or it may be patterned using an inorganic material film layer, depending on actual requirements. The pixel definition layer 13 defines multiple pixel openings 131, with the pixel openings 131 exposing the anode electrodes 1211 and the auxiliary electrode 1212.

In S132, different materials for the light-emitting layer 14 may be adopted to form the light-emitting layer 14, that include portions with different colors in the pixel openings 131, through vapor-deposition, such as a red light-emitting layer 14, a green light-emitting layer 14, and a blue light-emitting layer 14; or a white material of the light-emitting layer 14 may be adopted for vapor-deposition to form a white light-emitting layer 14. Subsequently, a color filter layer may be fabricated to achieve color display.

In S133, the cathode material is vapor-deposited such that the cathode material is deposited on each portion of the light-emitting layer 14 and the pixel definition layer 13, and extends to be deposited on the outermost auxiliary electrode 1212, forming an electrical connection with the auxiliary electrode 1212, thereby forming a continuous cathode electrode 15 across the entire surface. This design may improve the uniformity of the cathode signal and reduce voltage drop. Through S133, multiple array-distributed light-emitting units L are formed, where each anode electrode 1211, a corresponding portion of the light-emitting layer 14, and the cathode electrode 15 participate in forming the light-emitting unit L. The color of the light-emitting unit L depends on the light-emitting color of its electrode layer 121.

In the embodiments, the operation S13 may further include operation as followed.

At block S134: Preparing an encapsulation layer 16 on a side of the cathode electrode 15 away from the glass substrate 11 to encapsulate the light-emitting units L.

The encapsulation layer 16 may specifically be a multi-layer stack of an organic encapsulation layer and an inorganic encapsulation layer to ensure encapsulation effectiveness, thereby isolating external water and oxygen and preventing their intrusion, which could cause the light-emitting units L to malfunction.

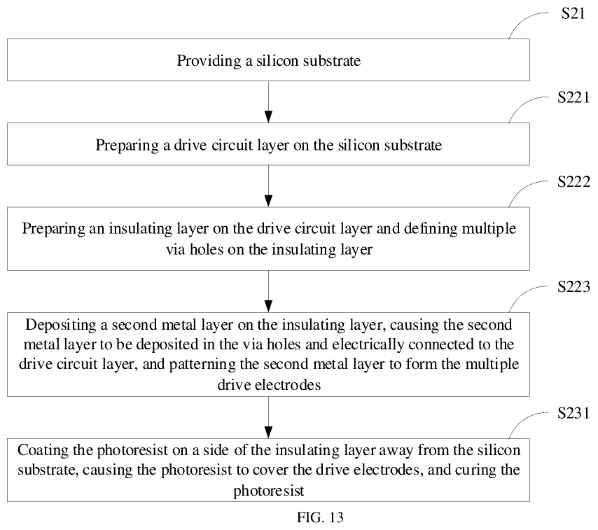

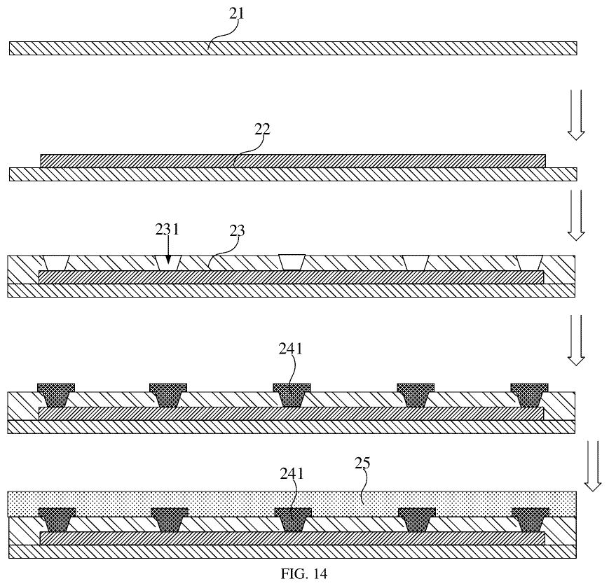

Referring to FIGS. 13 and 14, FIG. 13 is a flowchart of operation S20 in the manufacturing method as illustrated in FIG. 2 according to other embodiments of the present disclosure, and FIG. 14 is a schematic diagram of a manufacturing process of a drive substrate according to the embodiments as illustrated in FIG. 13. In the embodiments, the operation S20 of preparing the drive substrate 20 specifically includes operations at blocks illustrated in FIG. 13.

At block S21: Providing a silicon substrate 21.

At block S221: Preparing a drive circuit layer 22 on the silicon substrate 21.

At block S222: Preparing an insulating layer 23 on the drive circuit layer 22 and defining multiple via holes 231 on the insulating layer 23.

At block S223: Depositing a second metal layer on the insulating layer 23, causing the second metal layer to be deposited in the via holes 231 and electrically connected to the drive circuit layer 22, and patterning the second metal layer to form the multiple drive electrodes 241.

At block S231: Coating the photoresist PR on a side of the insulating layer 23 away from the silicon substrate 21, causing the photoresist PR to cover the drive electrodes 241, and curing the photoresist PR.

In S222, the insulating layer 23 may be an inorganic insulating layer 23, such as a silicon dioxide insulating layer 23; the insulating layer 23 may be etched to define the via holes 231. In S223, a second metal layer is deposited on the insulating layer 23 to form the second metal layer with a predetermined thickness, and the second metal layer is deposited to fill the via holes 231, thereby forming an electrical connection with the drive circuit layer 22 through the via holes 231. The second metal layer is then patterned to form the drive electrodes 241 at the via holes 231.

In S231, the second protective layer 25 is formed also using the photoresist PR, which is more convenient and does not require special materials for the protective layer. Additionally, using photoresist PR for the second protective layer 25 ensures a more reliable bond between the photoresist PR and the insulating layer 23 after curing, reducing the risk of delamination or peeling, and providing better protection for the protruding portions of the drive electrodes 241.

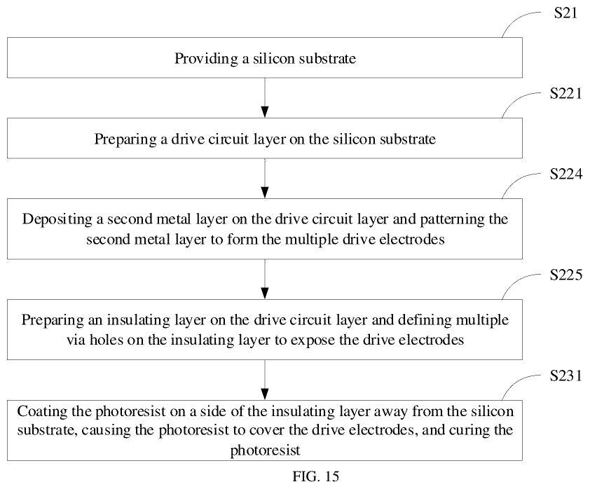

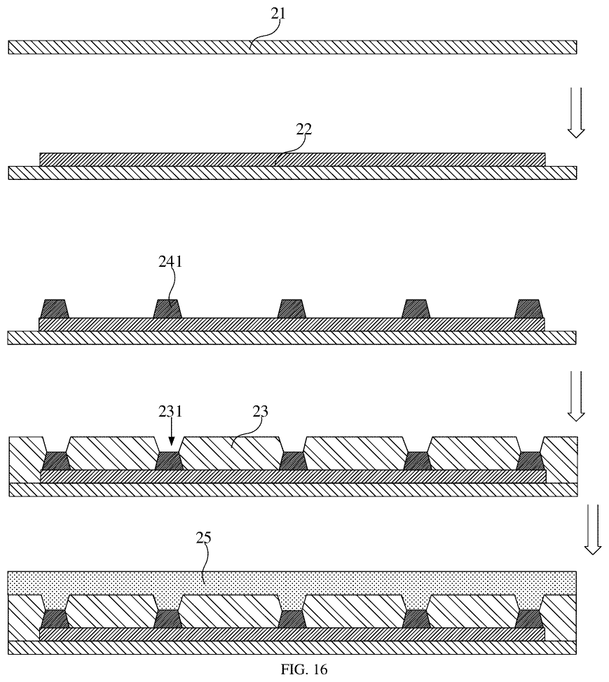

Referring to FIGS. 15 and 16, FIG. 15 is a flowchart of operation S20 in the manufacturing method as illustrated in FIG. 2 according to further other embodiments of the present disclosure, and FIG. 16 is a schematic diagram of a manufacturing process of a drive substrate according to the embodiments as illustrated in FIG. 15. In the embodiments, the operation S20 of preparing the drive substrate 20 specifically includes operations at blocks illustrated in FIG. 15.

At block S21: Providing a silicon substrate 21.

At block S221: Preparing a drive circuit layer 22 on the silicon substrate 21.

At block S224: Depositing a second metal layer on the drive circuit layer 22 and patterning the second metal layer to form the multiple drive electrodes 241.

At block S225: Preparing an insulating layer 23 on the drive circuit layer 22 and defining multiple via holes 231 on the insulating layer 23 to expose the drive electrodes 241.

At block S231: Coating the photoresist PR on a side of the insulating layer 23 away from the silicon substrate 21, causing the photoresist PR to cover the drive electrodes 241, and curing the photoresist PR.

Unlike the previous embodiments, in the present embodiments, the drive electrodes 241 are first formed, followed by the formation of the insulating layer 23. Specifically, in S225, in some embodiments, the depth of the via holes 231 may be greater than the height of the drive electrodes 241, such that the drive electrodes 241 are completely located within the via holes 231, forming a recessed structure between the drive electrodes 241 and the via holes 231. In this way, when the drive electrodes 241 are aligned and connected with the conductive portions 122 of the light-emitting substrate 10, the conductive portion 122 is embedded into the recessed structure to form alignment, i.e., the recessed structure serves as a guiding role during alignment to improve alignment accuracy and limiting the conductive portions 122 to prevent displacement after alignment. It should be noted that the protrusion height of the conductive portion 122 shall be greater than the depth of the recessed structure to facilitate connecting between the conductive portion 122 and the drive electrode 241 to form an electrical connection.

In the embodiments of the present disclosure, on the light-emitting substrate 10, the electrode layer 121 includes an anode electrode 1211 and an auxiliary cathode, with the auxiliary cathode located on an edge of the metal pattern layer 12; the conductive portions 122 include an anode connecting portion 1221 connected to the anode electrode 1211 and a cathode connecting portion 1222 connected to the auxiliary cathode. On the drive substrate 20, the drive electrodes 241 include an anode drive electrode 2411 and a cathode drive electrode 2412, with the cathode drive electrode 2412 located on an edge of the drive electrodes 241. The distribution design of the conductive portions 122 is matched with the distribution design of the drive electrodes 241 such that each conductive portion 122 can be aligned and connected with a corresponding drive electrode 241. The specific alignment and connecting method is described in detail below.

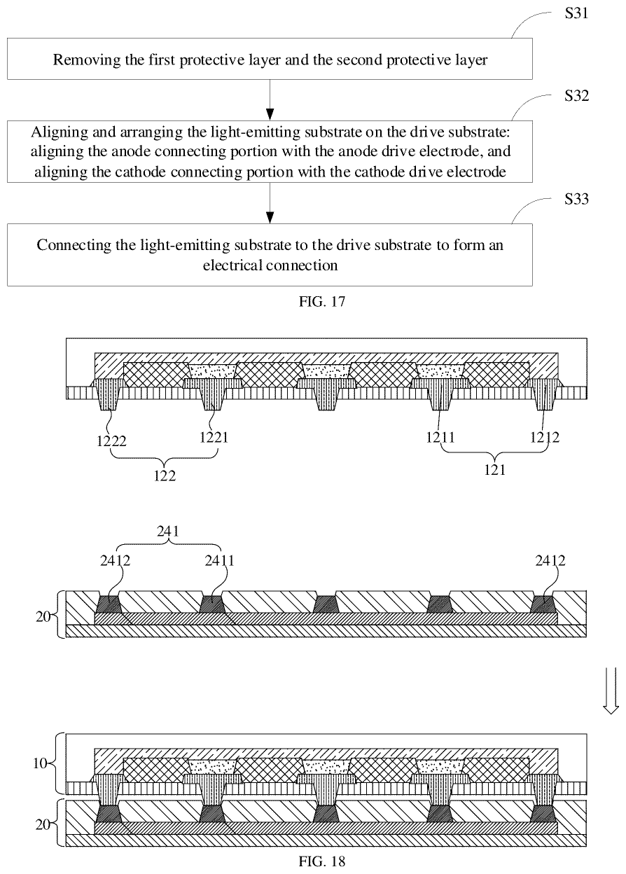

Referring to FIGS. 17 and 18, FIG. 17 is a flowchart of operation S30 in the manufacturing method as illustrated in FIG. 2 according to some embodiments of the present disclosure, and FIG. 18 is a schematic diagram of a process for connecting two substrates according to the embodiments as illustrated in FIG. 17. In the embodiments, the operation S30 specifically includes operations at blocks illustrated in FIG. 17.

At block S31: Removing the first protective layer 17 and the second protective layer 25.

At block S32: Aligning and arranging the light-emitting substrate 10 on the drive substrate 20: aligning the anode connecting portion 1221 with the anode drive electrode 2411, and aligning the cathode connecting portion 1222 with the cathode drive electrode 2412.

At block S33: Connecting the light-emitting substrate 10 to the drive substrate 20 to form an electrical connection.

In S31, the first protective layer 17 and the second protective layer 25 may be etched using an etching process to remove the first protective layer 17 and the second protective layer 25.

Through S32 and S33, the drive signals on the drive substrate 20 are transmitted to the anode electrodes 1211 and cathode electrode 15 of the light-emitting substrate 10, thereby driving the light-emitting units L to emit light. The structural configuration of each electrode is described in detail below.

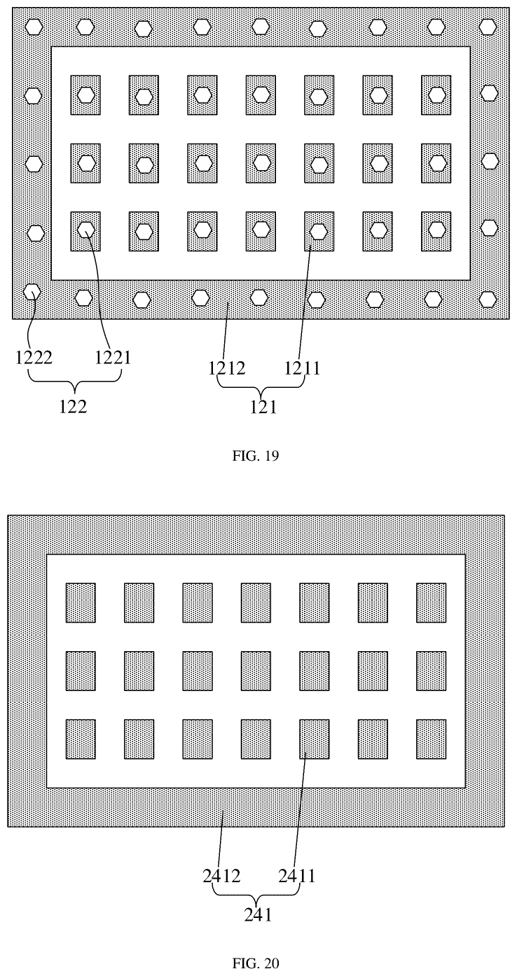

Referring to FIG. 19, FIG. 19 is a plane structural schematic view of a metal pattern layer according to some embodiments of the present disclosure. In the embodiments, the auxiliary cathode is ring-shaped and surrounds the multiple anode electrodes 1211. That is, on the metal pattern layer 12, the outermost ring-shaped electrode is the auxiliary cathode, and the anode electrodes 1211 are located in a region surrounded by the ring-shaped electrode.

The positive projection of the auxiliary cathode on the glass substrate 11 covers the cathode connecting portions 1222. Specifically, the cathode connecting portions 1222 are distributed along the annular shape of the auxiliary electrode 1212, and the cathode connecting portions 1222 may be spaced at equal intervals or arranged according to actual requirements, without necessarily being equally spaced. In this way, the cathode signals may be conducted through the cathode connecting portions 1222 to various parts of the auxiliary electrode 1212, thereby enhancing the reliability of signal transmission and the signal uniformity of the cathode electrode 15.

Referring to FIG. 20, FIG. 20 is a plane structural schematic view of a drive electrode according to some embodiments of the present disclosure. In the embodiments, the cathode drive electrode 2412 is ring-shaped and surrounds the anode drive electrodes 2411. That is, on a film layer where the drive electrodes 241 are disposed, the outermost ring-shaped electrode is the cathode drive electrode 2412, and the anode drive electrodes 2411 are located in a region surrounded by the cathode drive electrode 2412.

After the light-emitting substrate 10 is aligned with the drive substrate 20, the cathode connecting portions 1222 are located in the region of the cathode drive electrode 2412 in a direction perpendicular to the drive substrate 20. That is, after the light-emitting substrate 10 and the drive substrate 20 are aligned, the cathode connecting portions 1222 are entirely located directly above the cathode drive electrode 2412, thereby forming an electrical connection after connecting.

Refer to FIG. 21, FIG. 21 is a plane structural schematic view of a metal pattern layer according to other embodiments of the present disclosure. In the embodiments, the auxiliary cathodes are multiple and surround the multiple anodes. That is, the auxiliary electrodes 1212 are located on an outermost side and are multiple in number, surrounding the anodes. The arrangement of the multiple auxiliary electrodes 1212 ensures the uniformity of the cathode signals on the cathode electrode 15 while also facilitating the layout design of other signal lines in the first metal layer.

The positive projection of each auxiliary cathode on the glass substrate 11 covers at least one of the cathode connecting portions 1222. Specifically, each auxiliary electrode 1212 is configured to correspond at least one cathode connecting portion 1222, enabling the cathode signal to be conducted through at least one cathode connecting portion 1222 to each auxiliary electrode 1212, thereby enhancing signal transmission reliability and signal uniformity of the cathode electrode 15. The number of the cathode connecting portions 1222 corresponding to the auxiliary cathodes may be specifically determined based on the shape and size of the auxiliary cathodes.

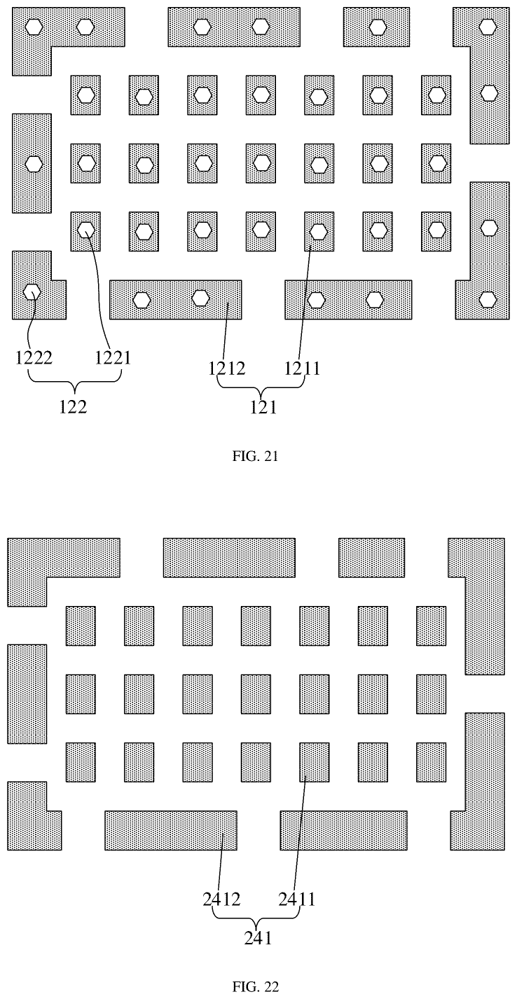

Referring to FIG. 22, FIG. 22 is a plane structural schematic view of a drive electrode according to other embodiments of the present disclosure. In the embodiments, the cathode drive electrodes 2412 are also multiple and surround the multiple anode drive electrodes 2411. That is, on the film layer where the drive electrodes 241 are disposed, multiple cathode drive electrodes 2412 are arranged on the outermost side, and the multiple cathode drive electrodes 2412 surround to define a region, with the anode drive electrodes 2411 located within this region.

Specifically, after the light-emitting substrate 10 is aligned with the drive substrate 20, each cathode drive electrode 2412 corresponds to at least one cathode connecting portion 1222 disposed above the cathode drive electrode 2412, such that the cathode connecting portions 1222 form electrical connections with the cathode drive electrodes 2411 after connecting, thereby enabling signal transmission.

After the light-emitting substrate 10 and the drive substrate 20 are aligned, each anode drive electrode 2411 corresponds to an anode connecting portion 1221 above it, such that after connecting, the anode electrode 1211 forms an electrical connection with the anode drive electrode 2411 to receive the drive signal from the anode drive electrode 2411, thereby achieving image display.

In the embodiments of the present disclosure, a light-emitting substrate 10 is further provided, as shown in FIG. 4. The specific structure of the light-emitting substrate 10 is the same or similar to that of the light-emitting substrate 10 obtained in FIG. 4 and can achieve the same technical effect. Specifically, the light-emitting substrate 10 includes:
a glass substrate 11;
a metal pattern layer 12, including an electrode layer 121 and conductive portions 122 that are interconnected; where the electrode layer 121 is disposed on a side of the glass substrate 11, and the conductive portions 122 penetrate the glass substrate 11 to an opposite side of the glass substrate 11 and partially protrude from the opposite side;
a protective layer, disposed on the opposite side of the glass substrate 11 and covering protruding portions of the conductive portions 122; and
a light-emitting device layer LD, disposed on a side of the electrode layer 121 away from the glass substrate 11.

The specific structures and functions of various components of the above-mentioned light-emitting substrate 10 are the same or similar to those of the light-emitting substrate 10 described in the above embodiments, and can achieve the same technical effects. The light-emitting substrate 10 may be manufactured using the above-mentioned manufacturing method, and specific details may be found in the detailed description of the above embodiment, which will not be repeated herein.

In the embodiments of the present disclosure, a drive substrate 20 is further provided, as shown in FIG. 6. The specific structure of the drive substrate 20 is the same or similar to that of the drive substrate 20 produced in FIG. 6 and can achieve the same technical effect. For details, reference may be made to the relevant description above, which will not be repeated herein.

The beneficial effects of the present disclosure: Distinct from the related art, the present disclosure provides a light-emitting substrate, a display panel, and a method for preparing the same. The method includes preparing a light-emitting substrate, preparing a drive substrate, and aligning and connecting the light-emitting substrate to the drive substrate. Light-emitting devices are prepared on a glass substrate to form the light-emitting substrate, and the light-emitting substrate is then connected to the drive substrate, enabling the light-emitting devices to be fabricated separately from the drive substrate. This may avoid the issue of damaging the drive circuits caused by directly depositing and fabricating the light-emitting devices on the drive substrate, thereby improving the product yield rate. Furthermore, the light-emitting substrate and the drive substrate are manufactured separately, which makes the preparation method more flexible and improves production efficiency. Furthermore, the preparation method provided by the embodiments of the present disclosure involves preparing a metal pattern layer and a first protective layer on opposite sides of the glass substrate, and causing the first protective layer to cover portions of the conductive portions of the metal pattern layer that protrude beyond the glass substrate to protect these protruding portions. This may prevent damage to the conductive portions during subsequent processes due to exposure of the protruding portions to equipment, which could cause signal transmission abnormalities or other issues. Similarly, by preparing a second protective layer on an insulating layer on a surface of the drive substrate, the second protective layer covers the exposed portions of the drive electrodes, thereby protecting the drive electrodes. This may prevent damage to the drive electrodes during subsequent storage, handling, or other operations caused by external forces or other external factors, which could result in signal transmission abnormalities or other issues.

The above is merely some embodiments of the present disclosure and does not limit the scope of the present disclosure. Any equivalent structures or equivalent process changes made based on the content of the specification and drawings of the present disclosure, or any direct or indirect application in other related technical fields, are similarly included within the scope of the present disclosure.

1. A manufacturing method of a display panel, comprising:
preparing a light-emitting substrate, comprising:
providing a glass substrate;
preparing a metal pattern layer on a side of the glass substrate, and preparing a first protective layer on an opposite side of the glass substrate; wherein the metal pattern layer comprises an electrode layer and conductive portions that are interconnected; the electrode layer is disposed on the side of the glass substrate, and the conductive portions penetrate the glass substrate to the opposite side of the glass substrate; a portion of each of the conductive portions protrudes from the opposite side; the first protective layer covers the portions of the conductive portions; and
preparing a light-emitting device layer on a side of the metal pattern layer away from the glass substrate;
preparing a drive substrate, comprising:
providing a silicon substrate; and preparing a drive circuit layer, drive electrodes, and an insulating layer on the silicon substrate; wherein the drive electrodes are electrically coupled to the drive circuit layer and extend through the insulating layer to be exposed; and
preparing a second protective layer on a side of the insulating layer away from the silicon substrate; wherein the second protective layer covers exposed portions of the drive electrodes; and
aligning and connecting the light-emitting substrate with the drive substrate, comprising:
removing the first protective layer and the second protective layer; and
aligning and connecting the conductive portions of the light-emitting substrate with the drive electrodes of the drive substrate.

2. The manufacturing method according to claim 1, wherein the preparing a light-emitting substrate further comprises: defining a plurality of glass through holes on the glass substrate;
wherein the forming a metal pattern layer on a side of the glass substrate, and forming a first protective layer on an opposite side of the glass substrate comprise:
preparing the metal pattern layer: depositing a first metal layer on the side of the glass substrate and performing pattern formation to form the electrode layer and the conductive portions; and
preparing the first protective layer: coating photoresist on the opposite side of the glass substrate, causing the photoresist to cover the plurality of glass through holes, and curing the photoresist to form the first protective layer.

3. The manufacturing method according to claim 2, wherein the preparing the metal pattern layer precedes the preparing the first protective layer;
before the depositing a first metal layer, the preparing the metal pattern layer further comprises:
aligning and arranging the glass substrate on a carrier plate; wherein an upper surface of the carrier plate defines a plurality of first recesses, and after the glass substrate is aligned and arranged on the carrier plate, the plurality of first recesses align with and communicate with the plurality of glass through holes.

4. The manufacturing method according to claim 3, wherein a number of the plurality of first recesses is greater or equal to a number of the plurality of glass through holes; a shape and depth of each first recess is adapted to the portion of a corresponding conductive portion.

5. The manufacturing method according to claim 3, wherein before the preparing the first protective layer, the forming a metal pattern layer on a side of the glass substrate, and forming a first protective layer on an opposite side of the glass substrate further comprise:
separating the carrier substrate from the glass substrate, and flipping the glass substrate for causing the opposite side of the glass substrate to be on top and the side of the glass substrate to be on bottom.

6. The manufacturing method according to claim 2, wherein the preparing the first protective layer precedes the preparing the metal pattern layer;
after the coating photoresist on the opposite side of the glass substrate, the preparing the first protective layer further comprises:
exposing and developing the photoresist to define a plurality of second recesses on a side of the photoresist close to the glass substrate, with the plurality of second recesses aligned and communicated to the plurality of glass through holes.

7. The manufacturing method according to claim 2, wherein the preparing a second protective layer on a side of the insulating layer away from the silicon substrate comprises:
coating photoresist on the insulating layer, causing the exposed portions of the drive electrodes, and curing the photoresist to form the second protective layer;
wherein the removing the first protective layer and the second protective layer comprises: etching the first protective layer and the second protective layer respectively to remove the first protective layer and the second protective layer.

8. The manufacturing method according to claim 7, wherein the electrode layer comprises anode electrodes and an auxiliary cathode, with the auxiliary cathode located on an edge of the metal pattern layer; the conductive portions comprise anode connecting portions connected to the anode electrodes and a cathode connecting portion connected to the auxiliary cathode; the drive electrodes comprise anode drive electrodes and a cathode drive electrode, with the cathode drive electrode located on an edge of the drive electrodes.

9. The manufacturing method according to claim 8, wherein the aligning and connecting the conductive portions of the light-emitting substrate with the drive electrodes of the drive substrate comprises:
aligning the anode connecting portions with the anode drive electrodes, and aligning the cathode connecting portion with the cathode drive electrode; and
connecting the light-emitting substrate to the drive substrate to form an electrical connection.

10. The manufacturing method according to claim 8, wherein
the auxiliary cathode is ring-shaped and surrounds the anode electrodes; the cathode drive electrode is ring-shaped and surrounds the anode drive electrodes;
wherein a positive projection of the auxiliary cathode on the glass substrate covers multiple the cathode connecting portions; after the light-emitting substrate is aligned with the drive substrate, the cathode connecting portions are located in a region of the cathode drive electrode in a direction perpendicular to the drive substrate.

11. The manufacturing method according to claim 8, wherein
the auxiliary cathode comprises a plurality of auxiliary cathodes, and the plurality of auxiliary cathodes surround the anode electrodes; the cathode drive electrode comprises a plurality of cathode drive electrodes; and the plurality of cathode drive electrodes surround the anode drive electrodes;
wherein a positive projection of the auxiliary cathode on the glass substrate covers multiple the cathode connecting portions; after the light-emitting substrate is aligned with the drive substrate, the cathode connecting portions are located in a region of the cathode drive electrodes in a direction perpendicular to the drive substrate.

12. The manufacturing method according to claim 1, wherein the forming a light-emitting device layer on a side of the metal pattern layer away from the glass substrate comprises:
preparing a pixel definition layer on the side of the glass substrate, defining pixel openings on the pixel definition layer, and causing the pixel openings to expose the electrode layer;
vapor-depositing material of a light-emitting layer, causing the material of the light-emitting layer to be deposited on the electrode layer within the pixel openings, for forming the light-emitting layer; and
vapor-depositing cathode material, and causing the cathode material to be deposited on the light-emitting layer and the pixel definition layer and to be extended and deposited on the electrode layer at an outermost position, for forming a cathode electrode.

13. The manufacturing method according to claim 12, wherein the light-emitting layer comprises layer portions disposed in the pixel openings in a one-to-one correspondence;
the layer portions are of different light-emitting colors; or
the layer portions are of a wight light-emitting color, and a color filter layer is arranged on a side of the cathode electrode away from the glass substrate.

14. The manufacturing method according to claim 12, wherein the forming a light-emitting device layer on a side of the metal pattern layer away from the glass substrate further comprises:
preparing an encapsulation layer on a side of the cathode electrode away from the glass substrate; wherein the encapsulation layer is configured to cover the cathode electrode along an extension direction of the light-emitting substrate.

15. The manufacturing method according to claim 1, wherein the preparing a drive circuit layer, drive electrodes, and an insulating layer on the silicon substrate comprises:
preparing the drive circuit layer on the silicon substrate;
preparing the insulating layer on the drive circuit layer and defining a plurality of via holes on the insulating layer; and
depositing a second metal layer on the insulating layer, causing the second metal layer to be deposited in the plurality of via holes and electrically connected to the drive circuit layer, and patterning the second metal layer to form the drive electrodes.

16. The manufacturing method according to claim 15, wherein the preparing a second protective layer on a side of the insulating layer away from the silicon substrate comprises:
coating photoresist on the side of the insulating layer away from the silicon substrate, causing the photoresist to cover the drive electrodes, and curing the photoresist to form the second protective layer.

17. The manufacturing method according to claim 1, wherein the preparing a drive circuit layer, drive electrodes, and an insulating layer on the silicon substrate comprises:
preparing the drive circuit layer on the silicon substrate;
depositing a second metal layer on the drive circuit layer and patterning the second metal layer to form the drive electrodes; and
preparing the insulating layer on the drive circuit layer and defining a plurality of via holes on the insulating layer to expose the drive electrodes.

18. The manufacturing method according to claim 17, wherein the preparing a second protective layer on a side of the insulating layer away from the silicon substrate comprises:
coating photoresist on the side of the insulating layer away from the silicon substrate, causing the photoresist to cover the drive electrodes, and curing the photoresist to form the second protective layer.

19. A light-emitting substrate, comprising:
a glass substrate;
a metal pattern layer, comprising an electrode layer and conductive portions that are interconnected; wherein the electrode layer is disposed on a side of the glass substrate, and the conductive portions penetrate the glass substrate to an opposite side of the glass substrate; a portion of each of the conductive portions protrudes from the opposite side;
a protective layer, disposed on the opposite side of the glass substrate and covering the portions of the conductive portions; and
a light-emitting device layer, disposed on a side of the electrode layer away from the glass substrate.

20. A display panel, comprising a drive substrate and a light-emitting substrate that are connected together; wherein the display panel is prepared by the manufacturing method according to claim 1.
